(19) United States
(12) Patent Application Publication
(10) Pub. No.: US 2024/0372036 A1
(43) Pub. Date: Nov. 7, 2024

(54) COMPOSITE SUBSTRATE, METHOD FOR PREPARING THE SAME, AND SEMICONDUCTOR STRUCTURE

(71) Applicant: Enkris Semiconductor (Wuxi), Ltd., Wuxi (CN)

(72) Inventor: Kai CHENG, Wuxi (CN)

(73) Assignee: Enkris Semiconductor (Wuxi), Ltd., Wuxi (CN)

(21) Appl. No.: 18/361,458

(22) Filed: Jul. 28, 2023

(30) Foreign Application Priority Data
May 4, 2023 (CN) 202310495131.0

(51) Int. Cl. H01L 33/32; H01L 33/00; H01L 33/16

(52) U.S. Cl. CPC H01L 33/32; H01L 33/007; H01L 33/0093; H01L 33/16

(57) ABSTRACT

Disclosed is a composite substrate, including: a supporting substrate, a patterned buried layer and a growth substrate which are stacked in sequence. The patterned buried layer is provided with a plurality of grooves at a side, away from the supporting substrate, of the patterned buried layer, and the growth substrate is located on the patterned buried layer and fills the plurality of grooves. At least portion of the growth substrate is located in the plurality of grooves, and at least portion of the growth substrate and at least portion of the patterned buried layer are staggered along a direction in which the plurality of grooves are arranged, so that a mechanical strength of the composite substrate is improved. In addition, the growth substrate is used for a subsequent epitaxial preparation of semiconductor devices, thereby improving performances of the prepared devices.

### CROSS-REFERENCE TO RELATED APPLICATIONS

The present application claims priority to Chinese Patent Application No. 202310495131.0, filed on May 4, 2023, all contents of which are incorporated herein in its entirety by reference.

### TECHNICAL FIELD

The present application relates to the field of semiconductor technologies, and in particular, to a composite substrate, a method for preparing the same, and a semiconductor structure.

### BACKGROUND

Gallium nitride-based (GaN-based) wide bandgap materials are particularly suitable for high-frequency, high-power and other applications due to their high performances. Especially in the field of semiconductor devices, significant progress and development have been made in the research of optoelectronic devices such as GaN-based Light Emitting Diode (LED), GaN-based Laser Diode (LD) and other optoelectronic devices, as well as GaN-based High Electron Mobility Transistor (HEMT) and other microelectronic devices.

### SUMMARY

In view of this, embodiments of the present application provide a composite substrate, a method for preparing the same, and a semiconductor structure, so as to solve the technical problems of low mechanical strength of a substrate.

According to an aspect of the present application, a composite substrate provided by an embodiment of the present application includes a supporting substrate, a patterned buried layer and a growth substrate which are stacked in sequence; the patterned buried layer is provided with a plurality of grooves at a side, away from the supporting substrate, of the patterned buried layer; and the growth substrate includes a first portion located in the plurality of grooves, and a second portion located on a side, away from the supporting substrate, of the first portion and covering the patterned buried layer.

In one embodiment, a material of the growth substrate is made of any one of the following materials: monocrystalline silicon, monocrystalline germanium, monocrystalline silicon germanium and monocrystalline silicon carbide.

In one embodiment, a surface, away from the supporting substrate, of the second portion is one of a (111) crystal plane, a (110) crystal plane and a (100) crystal plane.

In one embodiment, in a direction perpendicular to a plane in which the supporting substrate is located, a cross-sectional shape of the plurality of grooves includes any one of the following shapes: a rectangle, a trapezoid, an irregular quadrilateral, a triangle, a bowl and an arc.

In one embodiment, the composite substrate further includes a through hole located between the plurality of grooves and the supporting substrate, and the first portion fills the through hole.

In one embodiment, in a direction parallel to a plane in which the supporting substrate is located, a width of the through hole is less than or equal to 1 μm.

In one embodiment, a depth of the plurality of groove ranges from 1 nm to 2 μm.

In one embodiment, a depth of the plurality of grooves accounts for 1% to 99% of a thickness of the growth substrate.

In one embodiment, the supporting substrate is one of a silicon substrate, a sapphire substrate, a silicon carbide substrate and a ceramic substrate.

In one embodiment, the supporting substrate is a ceramic substrate, and the ceramic substrate is any one of the following substrates: an aluminum nitride ceramic substrate, a boron nitride ceramic substrate, a zirconia ceramic substrate, a magnesium oxide ceramic substrate, a silicon nitride ceramic substrate and a beryllium oxide ceramic substrate.

In one embodiment, a material of the patterned buried layer is made of any one of the following materials: silicon dioxide, silicon nitride and sapphire.

According to another aspect of the present application, a semiconductor structure provided by an embodiment of the present application includes the composite substrate as described in any one of the above embodiments, and an active structure layer located on a side, away from the patterned buried layer, of the growth substrate.

According to yet another aspect of the present application, a method for preparing a composite substrate provided by an embodiment of the present application includes: preparing a transition layer on a supporting substrate; patterning a side, away from the supporting substrate, of the transition layer to form a patterned buried layer with a plurality of grooves; and preparing a growth substrate on the patterned buried layer, the growth substrate includes a first portion located in the plurality of grooves, and a second portion located on a side, away from the supporting substrate, of the first portion and covering the patterned buried layer.

In one embodiment, when a material of the growth substrate is monocrystalline silicon, the preparing a growth substrate on the patterned buried layer includes: depositing amorphous silicon on the patterned buried layer; and converting, by using annealing, the amorphous silicon to the monocrystalline silicon.

In one embodiment, processing a surface, away from the supporting substrate, of the second portion is processed by using an alkaline solution, so that the surface, away from the supporting substrate, of the second portion becomes a (111) crystal plane.

In one embodiment, the method further includes preparing an active structural layer on a side, away from the supporting substrate, of the growth substrate.

In one embodiment, the method further includes: stripping off the supporting substrate; or stripping off the supporting substrate and the patterned buried layer.

In one embodiment, the method further includes preparing a through hole between the plurality of grooves and the supporting substrate, and the first portion fills the through hole.

In one embodiment, when the growth substrate is made of amorphous silicon, the amorphous silicon in the through hole crystallizes first, the amorphous silicon in the plurality of grooves crystallizes subsequently, and the amorphous silicon corresponding to the second portion crystallizes finally.

A composite substrate provided by the embodiments of the present application includes the supporting substrate, the patterned buried layer and the growth substrate which are stacked in sequence. The patterned buried layer is provided with a plurality of grooves at a side, away from the supporting substrate, of the patterned buried layer, and the first portion of the growth substrate is located in the plurality of grooves. The first portion and at least portion of the patterned buried layer are staggered along a direction in which the plurality of grooves are arranged, so that a mechanical strength of the composite substrate is improved. In addition, the second portion of the growth substrate is located at the side, away from the supporting substrate, of the first portion, which is used for a subsequent epitaxial preparation of a semiconductor structure, thereby improving device performances of the prepared semiconductor structure.

### BRIEF DESCRIPTION OF THE DRAWINGS

FIG. 1(a) to FIG. 1(f) are schematic structural diagrams of a composite substrate according to an embodiment.

FIG. 2 is a schematic structural diagram of a semiconductor structure according to an embodiment.

FIG. 3 is a schematic structural diagram of a semiconductor structure according to an embodiment.

FIG. 4 is a schematic structural diagram of a semiconductor structure according to an embodiment.

FIG. 5 is a schematic structural diagram of a composite substrate according to an embodiment.

FIG. 6 is a schematic structural diagram of a composite substrate according to an embodiment.

FIG. 7 is a flow diagram of a method for preparing a composite substrate according to an embodiment.

FIG. 8 to FIG. 10 are schematic structural diagrams of an intermediate structure generated when a composite substrate is prepared according to an embodiment.

FIG. 11 is a schematic structural diagram of a semiconductor structure according to an embodiment.

FIG. 12 is a schematic structural diagram of a semiconductor structure according to an embodiment.

FIG. 13 is a schematic structural diagram of a semiconductor structure according to an embodiment.

### DETAILED DESCRIPTIONS OF THE EMBODIMENTS

In the following, the technical schemes in the embodiments of the present application will be clearly and completely described with reference to the drawings in the embodiments of the present application. Obviously, the described embodiments are only a portion of the embodiments of the present application, but not all of them.

Recently, composite substrates, such as a SOI (Silicon on Insulator) substrate, have been gradually developed as substrates for semiconductor integrated circuits. By using the SOI substrate, a parasitic capacitance between a drain and a substrate of a transistor may be reduced, and therefore, the SOI substrate that can improve performances of an apparatus has attracted attention. However, in the case of preparing large-sized or curved devices, there is a problem of insufficient mechanical strength of the SOI substrate, which may cause cracking of the SOI substrate during preparing the device or using of the device. In addition, line-shaped defects and surface-shaped defects may also occur, which can reduce performances of the prepared device.

Since the mechanical strength of the SOI substrate is not enough, when the SOI substrate is utilized as the composite substrate, the composite substrate is prone to crack. In addition, there are many defects in a subsequent preparation of semiconductor devices, which affect the performances of the device.

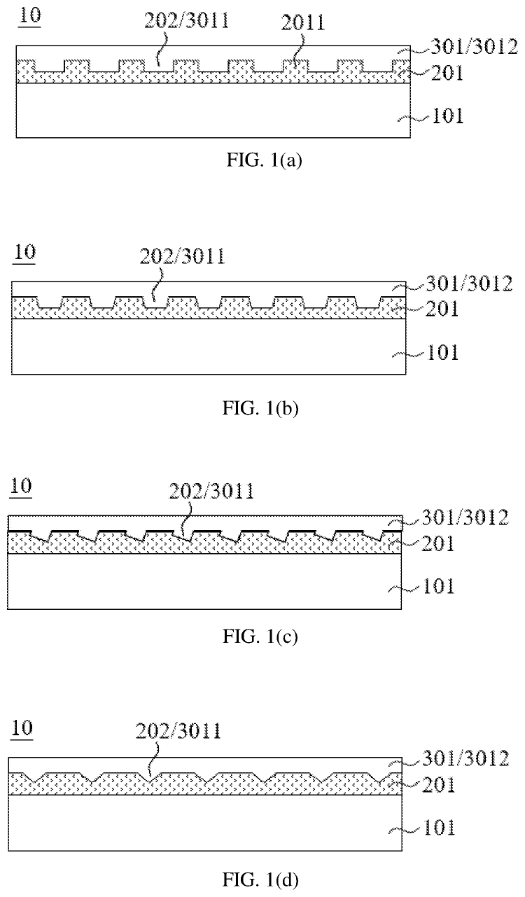

In order to solve the above problems, an embodiment of the application provides a composite substrate. FIG. 1(a) to FIG. 1(f) are schematic structural diagrams of a composite substrate according to an embodiment. As shown in FIG. 1(a), the composite substrate 10 provided by the embodiment of the present application includes a supporting substrate 101, a patterned buried layer 201 and a growth substrate 301 which are stacked in sequence. The patterned buried layer 201 is provided with a plurality of grooves 202 at a side, away from the supporting substrate 101, of the patterned buried layer 201; and the growth substrate 301 includes a first portion 3011 located in the plurality of grooves 202, and a second portion 3012 located on a side, away from the supporting substrate 101, of the first portion 3011 and covering the patterned buried layer 201.

The growth substrate 301 is located on the patterned buried layer 201 and fills the plurality of grooves 202, and the first portion 3011 is located in the plurality of grooves 202. The first portion 3011 and a convex portion 2011 of the patterned buried layer 201 are staggered along a direction in which the plurality of grooves 202 are arranged, which improves the mechanical strength of the composite substrate 10. In addition, the side, away from the supporting substrate 101, of the growth substrate 301 is a flat surface for the subsequent epitaxial preparation of the semiconductor devices, so that device performances of the prepared semiconductor structure can be improved.

Alternatively, there are at least two grooves 202 on the composite substrate 10, and a transverse dimension or a depth between the two grooves 202 is different.

In one embodiment, the supporting substrate 101 is one of a silicon substrate, a sapphire substrate, a silicon carbide substrate and a ceramic substrate. A thickness of the supporting substrate 101 reaches a micron scale. The silicon substrate has advantages such as a lower cost and a large preparation size. With the higher the concentration of impurities such as nitrogen, oxygen or carbon in silicon substrate, the greater the mechanical strength of the composite substrate. The ceramic substrate has advantages such as a high bonding strength and a high hardness, and therefore, the ceramic substrate can be used to make the composite substrate with a high mechanical strength.

Alternatively, the ceramic substrate is any one of the following substrates: an aluminum nitride ceramic substrate, a boron nitride ceramic substrate, a zirconia ceramic substrate, a magnesium oxide ceramic substrate, a silicon nitride ceramic substrate and a beryllium oxide ceramic substrate.

In one embodiment, a material of the patterned buried layer 201 is any one of the following materials: silicon dioxide, silicon nitride and sapphire. The silicon dioxide and the silicon nitride are insulating materials, and it is able to improve a resistivity of the composite substrate 10 by making these insulating materials into the patterned buried layer 201, so as to prepare high-frequency and low-loss semiconductor devices. Similarly, the sapphire is the insulating material, which has a relatively small thermal mismatch with the ceramic substrate, which may improve the mechanical strength of the composite substrate 10.

In one embodiment, a material of the growth substrate 301 is any one of the following materials: monocrystalline silicon, monocrystalline germanium, monocrystalline silicon germanium and monocrystalline silicon carbide. Alternatively, a surface, away from the supporting substrate 101, of the second portion 3012 of the growth substrate 301 is one of a (111) crystal plane, a (110) crystal plane and a (100) crystal plane. The growth substrate 301 is used for a subsequent epitaxial growth of an active structure layer to prepare a semiconductor structure. The (111) crystal plane, the (110) crystal plane and the (100) crystal plane of the monocrystalline silicon are more conducive to the epitaxial growth of the active structure layer (such as an epitaxial structure layer made of an III-V compound material). Alternatively, the active structure layer epitaxially prepared on the (111) crystal plane of the monocrystalline silicon has a better crystal quality.

In one embodiment, in a direction perpendicular to a plane in which the supporting substrate 101 is located, a cross-sectional shape of the grooves 202 includes any one of the following shapes: a rectangle (shown in FIG. 1(a)), a trapezoid (shown in FIG. 1(b)), an irregular quadrilateral (shown in FIG. 1(c)), a triangle (shown in FIG. 1(d)), a bowl (shown in FIG. 1(e)) and an arc (shown in FIG. 1(f)).

As shown in FIG. 1(a), the grooves 202 have side walls perpendicular to an upper surface of the growth substrate 301, and the cross-sectional shape of the grooves 202 is rectangular; as shown in FIG. 1(b) to FIG. 1(d), the side walls of the grooves 202 are all composed of straight lines; as shown in FIG. 1(e), the cross-sectional shape of the grooves 202 is bowl-shaped, the side walls of the grooves 202 are all composed of curved lines, and a lower surface of the grooves 202 are flat; as shown in FIG. 1(f), the side walls of the grooves 202 are all composed of the curved lines, and the lower surfaces of the grooves 202 are curved as a whole.

In one embodiment, a band gap width of the growth substrate 301 is less than that of the patterned buried layer 201; and/or, a band gap width of the patterned buried layer 201 is less than that of the supporting substrate 101. For example, the band gap width of the growth substrate 301 is less than that of the patterned buried layer 201, the supporting substrate 101 and the patterned buried layer 201 may be stripped off by using laser stripping, and the stripping is performed at an interface between the growth substrate 301 and the patterned buried layer 201, so as to obtain a relatively thin composite substrate. For another example, the band gap width of the patterned buried layer 201 is less than that of the supporting substrate 101, the supporting substrate 101 may be stripped off by using the laser stripping, and the stripping is performed at an interface between the patterned buried layer 201 and the supporting substrate 101, so as to obtain a relatively thin composite substrate.

In one embodiment, as shown in FIG. 1(e), a depth h1 of the grooves 202 ranges from 1 nm to 2 μm. Alternatively, the depth h1 of the grooves 202 ranges from 5 nm to 100 nm.

In one embodiment, the depth h1 of the grooves 202 accounts for 1% to 99% of a thickness h2 of the growth substrate 301. Alternatively, the depth h1 of the grooves 202 accounts for 10% to 90% of the thickness h2 of the growth substrate 301. If the depth of the grooves 202 is too large, the growth substrate with a large plane area may not be prepared, and if the depth of the grooves 202 is too small, the mechanical strength of the composite substrate may not be improved. Alternatively, a thickness h2 of the growth substrate 301 ranges from 10 nm to 150 nm. Alternatively, a thickness h3 of the patterned buried layer 201 ranges from 10 nm to 150 nm, so as to achieve an ultra-thin composite substrate. Alternatively, a sum of the thicknesses of the patterned buried layer 201 and the growth substrate 301 ranges from 15 nm to 300 nm.

Alternatively, the supporting substrate 101 is the silicon substrate, the material of the patterned buried layer 201 is the silicon dioxide, the material of the growth substrate 301 is the monocrystalline silicon, and the composite substrate 10 is the SOI substrate. The sum of the thicknesses of the patterned buried layer 201 and the growth substrate 301 ranges from 15 nm to 300 nm, so that the ultra-thin SOI substrate may be realized. When the ultra-thin SOI substrate is used for preparing the semiconductor devices of the transistor, a depletion layer prepared at a channel below a gate in a working state fills the whole growth substrate 301, which may reduce a parasitic capacitance of the devices and improve the performances of the devices.

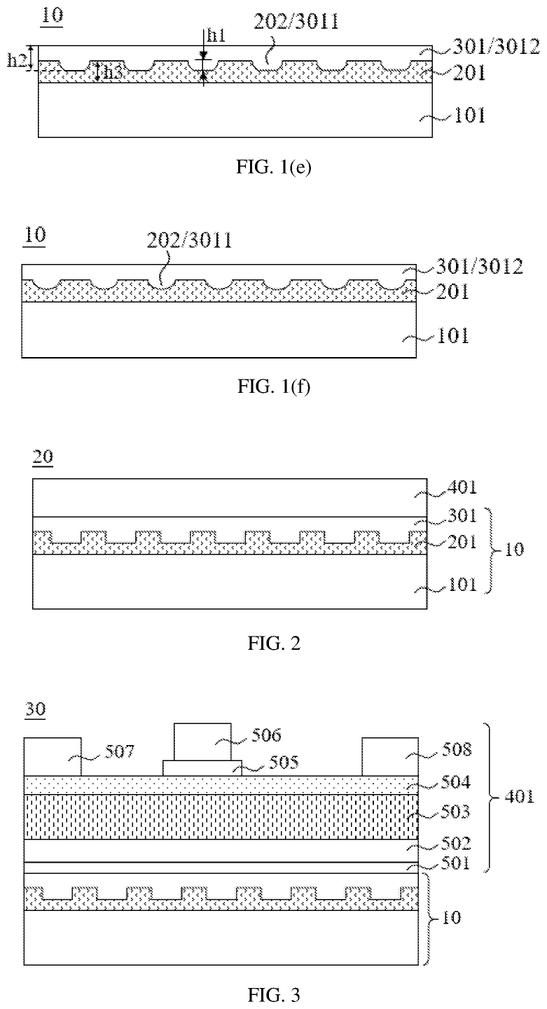

An embodiment of the present application also provides a semiconductor structure, and FIG. 2 is a structural schematic diagram of a semiconductor structure according to an embodiment. As shown in FIG. 2, the semiconductor structure 20 includes the composite substrate 10 described in any of the above embodiments and an active structure layer 401 located at a side, away from the patterned buried layer 201, of the growth substrate 301. It should be noted that FIG. 2 is only illustrated by the rectangular cross-sectional shape of the grooves 202.

Alternatively, FIG. 3 is a structural schematic diagram of a semiconductor structure according to an embodiment, as shown in FIG. 3, when the semiconductor structure 30 is a transistor, the active structure layer 401 includes a nucleation layer 501, a buffer layer 502, a channel layer 503 and a barrier layer 504, which are sequentially arranged on the composite substrate 10. The active structure layer 401 also includes a gate 506, a source 507 and a drain 508 located above the barrier layer 504. Alternatively, there is also a cap layer 505 between the gate 506 and the barrier layer 504. Alternatively, the semiconductor structure 30 is a GaN-based HEMT device, and the cap layer 505 may be p-GaN.

After the composite substrate 10 with such a structure is prepared, the overall mechanical strength of the semiconductor structure 30 may be improved, and since a high-resistance substrate is provided, performances of the transistor are improved.

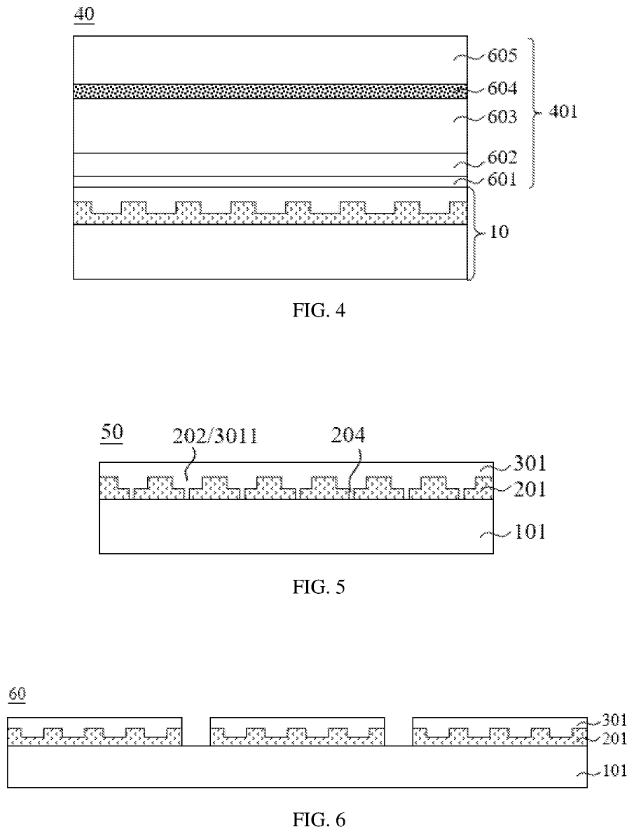

Alternatively, FIG. 4 is a schematic structural diagram of a semiconductor structure according to an embodiment, as shown in FIG. 4, when the semiconductor structure 40 is used for preparing a light-emitting diode, the active structure layer 401 includes a nucleation layer 601, a buffer layer 602, an N-type semiconductor layer 603, an active layer 604 and a P-type semiconductor layer 605 which are sequentially arranged on the composite substrate 10. It should be noted that an electrode structure is not shown in FIG. 4, so the semiconductor structure 40 may be an intermediate structure generated when the light emitting device is prepared.

The structure of the composite substrate 10 may also be a structure in which the supporting substrate is stripped off. In the subsequent preparation of the semiconductor structure 40, since the composite substrate 10 with this structure has a relatively high mechanical strength, a probability of defect occurrence may be reduced, and the performances of the semiconductor structure may be improved.

In one embodiment, FIG. 5 is a schematic structural diagram of a semiconductor structure according to an embodiment, as shown in FIG. 5, the composite substrate 50 further includes a through hole 204, which is located between the grooves 202 and the supporting substrate 101, and the first portion 3011 of the growth substrate 301 fills the through hole 204.

As shown in FIG. 5, the first portion 3011 of the growth substrate 301 is prepared in the through hole 204 and the grooves 202, and the second portion 3012 of the growth substrate 301 is prepared on a side, away from the supporting substrate 101, of the first portion 3011 and covers the patterned buried layer 201. Alternatively, when the growth substrate 301 is made of amorphous silicon, the amorphous silicon in the through hole 204 crystallizes first, the amorphous silicon in the grooves 202 crystallizes subsequently, and the second portion 3012 of the growth substrate 301 crystallizes finally, so that the obtained growth substrate 301 has a better single crystal quality.

Alternatively, in a direction parallel to a plane in which the supporting substrate 101 is located, a width of the through hole 204 is less than or equal to 1 μm. Alternatively, in the direction parallel to the plane in which the supporting substrate 101 is located, when a cross section of the through hole 204 is circular, a diameter of the through hole 204 is less than or equal to 1 μm.

In one embodiment, FIG. 6 is a schematic structural diagram of a composite substrate according to an embodiment, as shown in FIG. 6, the composite substrate 60 includes the supporting substrate 101, a plurality of patterned buried layers 201 which are arranged on the supporting substrate 101, and a growth substrate 301 located on the patterned buried layers 201, and then an independent active structure layer 401 may be epitaxially prepared on the growth substrate 301. Alternatively, FIG. 6 illustrates three groups of the patterned buried layer 201 and the growth substrate 301. The number of groups of the patterned buried layer 201 and the growth substrate 301 on one supporting substrate 101 is not limited in the embodiments.

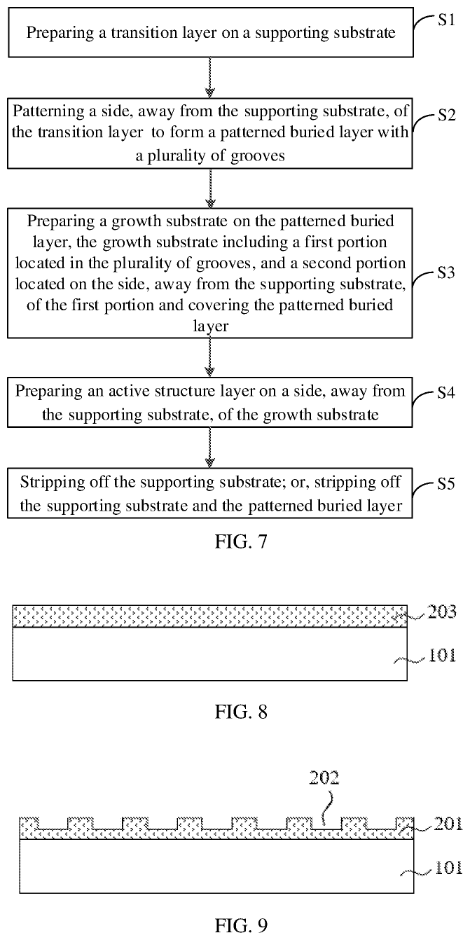

An embodiment of the present application also provides a method for preparing a composite substrate. FIG. 7 is a flow diagram of a method for preparing a composite substrate according to an embodiment, and FIG. 8 to FIG. 10 are schematic structural diagrams of an intermediate structure generated when the composite substrate is prepared according to an embodiment. As shown in FIG. 7, the method includes the following contents.

In the step S1, as shown in FIG. 8, preparing a transition layer 203 on a supporting substrate 101. Alternatively, when the transition layer 203 is made of silicon dioxide, the transition layer 203 may be prepared by using chemical vapor deposition; when the transition layer 203 is made of sapphire, the transition layer 203 may be prepared by using electron beam deposition or sputtering deposition; and when the supporting substrate 101 is a silicon substrate and the transition layer 203 is made of the silicon dioxide, the silicon substrate is processed by using thermal oxidation to form the transition layer 203 on an upper surface of the supporting substrate 101.

In the step S2, as shown in FIG. 9, patterning a side, away from the supporting substrate 101, of the transition layer 203 to form a patterned buried layer 201 with a plurality of grooves 202. Alternatively, when the patterning is dry etching, the composite substrate 10 with the grooves composed of linear side walls shown in FIG. 1(a) to FIG. 1(d) may be prepared by etching with a mask such as photoresist, or the composite substrate 10 with the grooves composed of the linear side walls shown in FIG. 1(a) to FIG. 1(c) may be prepared by etching with inductively coupled plasma. Alternatively, when the patterning is wet etching, the composite substrate 10 with the grooves composed of curved side walls shown in FIG. 1(e) and FIG. 1(f) may be prepared.

In the step S3, as shown in FIG. 7, preparing a growth substrate 301 on the patterned buried layer 201, the growth substrate 301 including a first portion 3011 located in the plurality of grooves 202, and a second portion 3012 located on the side, away from the supporting substrate 101, of the first portion 3011 and covering the patterned buried layer 201.

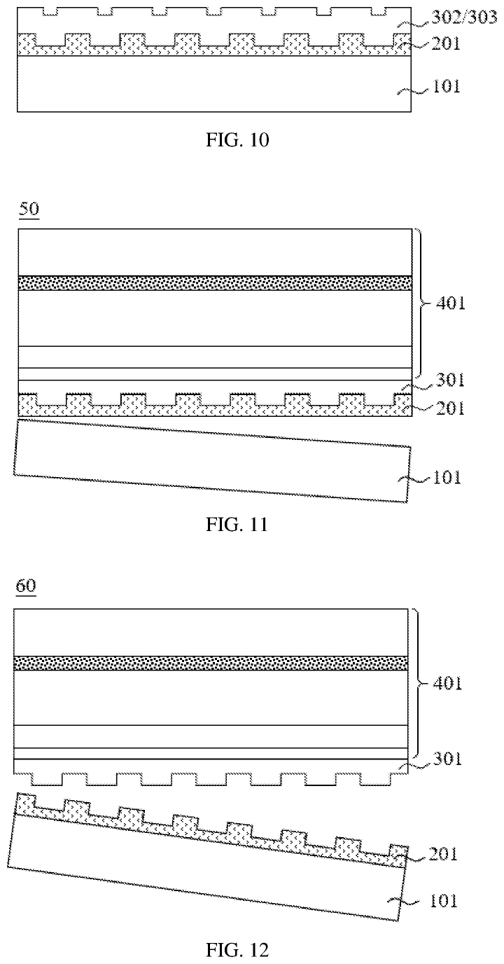

In one embodiment, as shown in FIG. 10, amorphous silicon 302 is deposited on the patterned buried layer 201, and the amorphous silicon 302 is converted to monocrystalline silicon 303 by using annealing. Alternatively, the annealing is laser annealing. Alternatively, after the monocrystalline silicon 303 is formed, chemical mechanical polishing is performed on a surface, away from the supporting substrate 101, of the monocrystalline silicon 303, and therefore, as shown in FIG. 1(a), the side, away from the supporting substrate 101, of the growth substrate 301 becomes a flat surface.

In one embodiment, a surface, away from the supporting substrate 101, of the second portion 3012 of the growth substrate 301 is processed by using an alkaline solution, so that the surface, away from the supporting substrate 101, of the second portion 3012 becomes a (111) crystal plane. The growth substrate 301 is used for a subsequent epitaxial growth of an active structure layer to prepare the semiconductor structure, and the (111) crystal plane of the monocrystalline silicon is more conducive to the epitaxial growth of the active structure layer (for example, an epitaxial structure layer made of III-V compound materials).

In one embodiment, as shown in FIG. 7, the method further includes S4, preparing an active structure layer 401 on a side, away from the supporting substrate 101, of the growth substrate 301. Alternatively, as shown in FIG. 3, the semiconductor structure 30 made using the active structure layer 401 is a transistor; and as shown in FIG. 4, the semiconductor structure 40 made using the active structure layer 401 is a light emitting diode.

In one embodiment, as shown in FIG. 7, the method further includes S5, stripping off the supporting substrate 101; or, stripping off the supporting substrate 101 and the patterned buried layer 201.

Alternatively, taking a light-emitting diode as an example of the semiconductor structure, FIG. 11 is a schematic structural diagram of a semiconductor structure according to an embodiment. The supporting substrate 101 of the semiconductor structure 40 shown in FIG. 4 is removed to obtain the semiconductor structure 50 shown in FIG. 11, and the supporting substrate 101 may be reused later to prepare the composite substrate 10. Alternatively, the way to strip off the supporting substrate 101 is laser stripping, a bandgap width of the supporting substrate 101 is greater than that of the patterned buried layer 201, and a laser energy is between the two bandgap widths, so as to strip off the supporting substrate 101.

Alternatively, taking a light-emitting diode as an example of the semiconductor structure, FIG. 12 is a schematic structural diagram of a semiconductor structure according to an embodiment. The supporting substrate 101 and the patterned buried layer 201 of the semiconductor structure 40 shown in FIG. 4 are removed to obtain the semiconductor structure 60 shown in FIG. 12, and the supporting substrate 101 and the patterned buried layer 201 may be reused later to prepare the composite substrate 10.

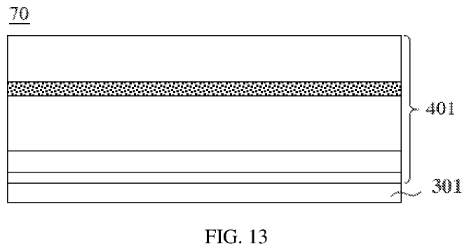

Alternatively, FIG. 13 is a schematic structural diagram of a semiconductor structure according to an embodiment. As shown in FIG. 13, the chemical mechanical polishing is performed on a surface, away from the active structure layer 401, of the growth substrate 301 to obtain the growth substrate 301 with a flat surface on the side away from the active structure layer 401. Alternatively, the way to strip off the supporting substrate 101 and the patterned buried layer 201 is laser stripping. The bandgap widths of the supporting substrate 101 and the patterned buried layer 201 are both greater than that of the growth substrate 301, and the laser energy is greater than the bandgap width of the growth substrate 301 and less than that of any one of the supporting substrate 101 and the patterned buried layer 201, thus realizing stripping off the supporting substrate 101 and the patterned buried layer 201.

A composite substrate provided by the present application includes a supporting substrate, a patterned buried layer and a growth substrate which are stacked in sequence, there are a plurality of grooves on a side, away from the supporting substrate, of the patterned buried layer, and the growth substrate is located on the patterned buried layer and fills the plurality of grooves. At least portion of the growth substrate is located in the plurality of grooves, and at least portion of the growth substrate and at least portion of the patterned buried layer are staggered along a direction in which the plurality of grooves are arranged, so that the mechanical strength of the composite substrate is improved. In addition, the growth substrate is used for the subsequent epitaxial preparation of the semiconductor devices, thereby improving the performances of the prepared devices.

It should be understood that the term “including” and its variations used in this application are open-ended including, that is, “including but not limited to”. The term “one embodiment” means “at least one embodiment”. In this specification, specific features, structures, materials or characteristics described may be combined in any one or more embodiments or examples in a suitable manner. In addition, those skilled in the art may combine and constitute different embodiments or examples and features of different embodiments or examples described in this specification without contradicting each other.

What is claimed is:

1. A composite substrate, comprising: a supporting substrate, a patterned buried layer and a growth substrate which are stacked in sequence;
wherein the patterned buried layer is provided with a plurality of grooves at a side, away from the supporting substrate, of the patterned buried layer; and
the growth substrate comprises a first portion located in the plurality of grooves, and a second portion located on a side, away from the supporting substrate, of the first portion and covering the patterned buried layer.

2. The composite substrate according to claim 1, wherein a material of the growth substrate is any one of the following materials: monocrystalline silicon, monocrystalline germanium, monocrystalline silicon germanium and monocrystalline silicon carbide.

3. The composite substrate according to claim 1, wherein a surface, away from the supporting substrate, of the second portion is one of a (111) crystal plane, a (110) crystal plane and a (100) crystal plane.

4. The composite substrate according to claim 1, wherein in a direction perpendicular to a plane in which the supporting substrate is located, a cross-sectional shape of the plurality of grooves comprises any one of the following shapes: a rectangle, a trapezoid, an irregular quadrilateral, a triangle, a bowl and an arc.

5. The composite substrate according to claim 1, further comprising a through hole located between the plurality of grooves and the supporting substrate, the first portion filling the through hole.

6. The composite substrate according to claim 5, wherein in a direction parallel to a plane in which the supporting substrate is located, a width of the through hole is less than or equal to 1 μm.

7. The composite substrate according to claim 1, wherein a depth of the plurality of grooves ranges from 1 nm to 2 μm.

8. The composite substrate according to claim 1, wherein a depth of the plurality of grooves accounts for 1% to 99% of a thickness of the growth substrate.

9. The composite substrate according to claim 1, wherein the supporting substrate is one of a silicon substrate, a sapphire substrate, a silicon carbide substrate and a ceramic substrate.

10. The composite substrate according to claim 1, wherein the supporting substrate is a ceramic substrate, and the ceramic substrate is any one of the following substrates: an aluminum nitride ceramic substrate, a boron nitride ceramic substrate, a zirconia ceramic substrate, a magnesium oxide ceramic substrate, a silicon nitride ceramic substrate and a beryllium oxide ceramic substrate.

11. The composite substrate according to claim 1, wherein a material of the patterned buried layer is any one of the following materials: silicon dioxide, silicon nitride and sapphire.

12. A semiconductor structure, comprising: a composite substrate,
wherein the composite substrate comprises a supporting substrate, a patterned buried layer and a growth substrate which are stacked in sequence; the patterned buried layer is provided with a plurality of grooves at a side, away from the supporting substrate, of the patterned buried layer; and the growth substrate comprises a first portion located in the plurality of grooves, and a second portion located on a side, away from the supporting substrate, of the first portion and covering the patterned buried layer; and
the semiconductor structure further comprises an active structure layer located on a side, away from the patterned buried layer, of the growth substrate.

13. The semiconductor structure according to claim 12, wherein a surface, away from the supporting substrate, of the second portion is one of a (111) crystal plane, a (110) crystal plane and a (100) crystal plane.

14. A method for preparing a composite substrate, comprising:
preparing a transition layer on a supporting substrate;
patterning a side, away from the supporting substrate, of the transition layer to form a patterned buried layer with a plurality of grooves; and
preparing a growth substrate on the patterned buried layer,
wherein the growth substrate comprises a first portion located in the plurality of grooves, and a second portion located on a side, away from the supporting substrate, of the first portion and covering the patterned buried layer.

15. The method according to claim 14, wherein when a material of the growth substrate is monocrystalline silicon, the preparing a growth substrate on the patterned buried layer comprises:
depositing amorphous silicon on the patterned buried layer; and
converting, by using annealing, the amorphous silicon into the monocrystalline silicon.

16. The method according to claim 14, wherein a surface, away from the supporting substrate, of the second portion is processed by using an alkaline solution, so that the surface, away from the supporting substrate, of the second portion becomes a (111) crystal plane.

17. The method according to claim 14, further comprising:
preparing an active structural layer on a side, away from the supporting substrate, of the growth substrate.

18. The method according to claim 14, further comprising:
stripping off the supporting substrate; or
stripping off the supporting substrate and the patterned buried layer.

19. The method according to claim 14, further comprising:
preparing a through hole between the plurality of grooves and the supporting substrate,
wherein the first portion fills the through hole.

20. The method according to claim 19, wherein when the growth substrate is made of amorphous silicon, the amorphous silicon in the through hole crystallizes first, the amorphous silicon in the plurality of grooves crystallizes subsequently, and the amorphous silicon corresponding to the second portion crystallizes finally.
